(19) United States
(12) Patent Application Publication
(10) Pub. No.: US 2025/0087461 A1
(43) Pub. Date: Mar. 13, 2025

(54) PULSED VOLTAGE-ASSISTED PLASMA STRIKE

(71) Applicant: Applied Materials, Inc., Santa Clara, CA (US)

(72) Inventors: Shreeram Jyoti DASH, San Jose, CA (US); Michael T. NICHOLS, Sunnyvale, CA (US)

(21) Appl. No.: 18/827,924

(22) Filed: Sep. 9, 2024

Related U.S. Application Data
(60) Provisional application No. 63/581,964, filed on Sep. 11, 2023.

(51) Int. Cl. H01J 37/32

(52) U.S. Cl. CPC H01J 37/32146; H01J 37/32128; H01J 37/32183; H01J 37/32935; H01J 2237/3341

(57) ABSTRACT

Embodiments provided herein generally include apparatus, plasma processing systems and methods for controlling plasma initiation and maintenance. Some embodiments are directed to an apparatus for processing a substrate in a plasma processing system. The apparatus generally includes: a pulsed voltage (PV) signal generator configured to provide a bias signal to a plasma load to initiate a plasma in a plasma chamber, wherein the bias signal comprises a first burst having a first duration, the first burst including a series of pulses; and a radio frequency (RF) signal generator configured to provide an RF signal to the plasma load for a second duration, wherein the first duration is less than 10% of the second duration, and wherein the first burst occurs at a beginning of the second duration.

### CROSS-REFERENCE TO RELATED APPLICATION

The present application for patent claims the benefit of priority to U.S. Provisional Patent Appl. No. 63/581,964, filed Sep. 11, 2023, which is hereby incorporated by reference herein in its entirety.

### BACKGROUND

### Field

Embodiments of the present disclosure generally relate to a system and methods used in semiconductor device manufacturing. More specifically, embodiments of the present disclosure relate to a plasma processing system used to process a substrate.

### Description of the Related Art

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

A typical RIE plasma processing chamber includes a radio frequency (RF) bias generator, which supplies an RF voltage to a power electrode. In a capacitive coupled gas discharge, the plasma is created by using an RF generator that is coupled to the power electrode that is disposed within an electrostatic chuck (ESC) assembly or within another portion of the processing chamber. In some cases, it may be challenging to ignite a plasma within the chamber, or the plasma may not be maintained long enough for processing substrate.

Therefore, there is a need for an apparatus and method for processing a substrate in a plasma processing system that solves the problems described above.

### SUMMARY

Embodiments provided herein generally include apparatus, plasma processing systems and methods for igniting and maintaining a plasma in a processing chamber.

Some embodiments are directed to an apparatus for processing a substrate in a plasma processing system. The apparatus generally includes: a pulsed voltage (PV) signal generator configured to provide a bias signal to a plasma load to initiate a plasma in a plasma chamber, wherein the bias signal comprises a first burst having a first duration, the first burst including a series of pulses; and a radio frequency (RF) signal generator configured to provide an RF signal to the plasma load for a second duration, wherein the first duration is less than 10% of the second duration, and wherein the first burst occurs at a beginning of the second duration.

Some embodiments are directed to a method for processing a substrate in a plasma processing system. The method generally includes: providing, via a pulsed voltage (PV) signal generator, a bias signal to a plasma load to initiate a plasma in a plasma chamber, wherein the bias signal comprises a first burst having a first duration, the first burst including a series of pulses; and providing, via a radio frequency (RF) signal generator, an RF signal to the plasma load for a second duration, wherein the first duration is less than 10% of the second duration, and wherein the first burst occurs at a beginning of the second duration.

Some embodiments are directed to a plasma processing system. The plasma processing system generally includes: a plasma chamber; a pulsed voltage (PV) signal generator coupled to the plasma chamber and configured to provide a bias signal to a plasma load to initiate a plasma in the plasma chamber, wherein the bias signal comprises a first burst having a first duration; and a radio frequency (RF) signal generator coupled to the plasma chamber and configured to provide an RF signal to the plasma load for a second duration, wherein the first duration is less than 10% of the second duration, and wherein the first burst occurs at a beginning of the second duration.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic representation of a plasma processing system, in accordance with certain embodiments of the present disclosure.

FIG. 1B is a schematic detailed cross-sectional view of the plasma processing system, in accordance with certain embodiments of the present disclosure.

FIG. 2 shows a voltage waveform that is established on a substrate due to a voltage waveform applied to an electrode of a processing chamber, in accordance with certain embodiments of the present disclosure.

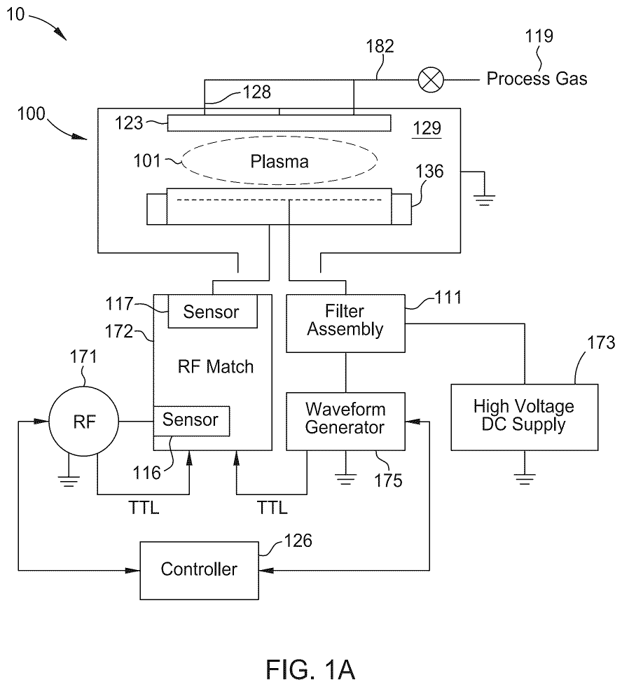

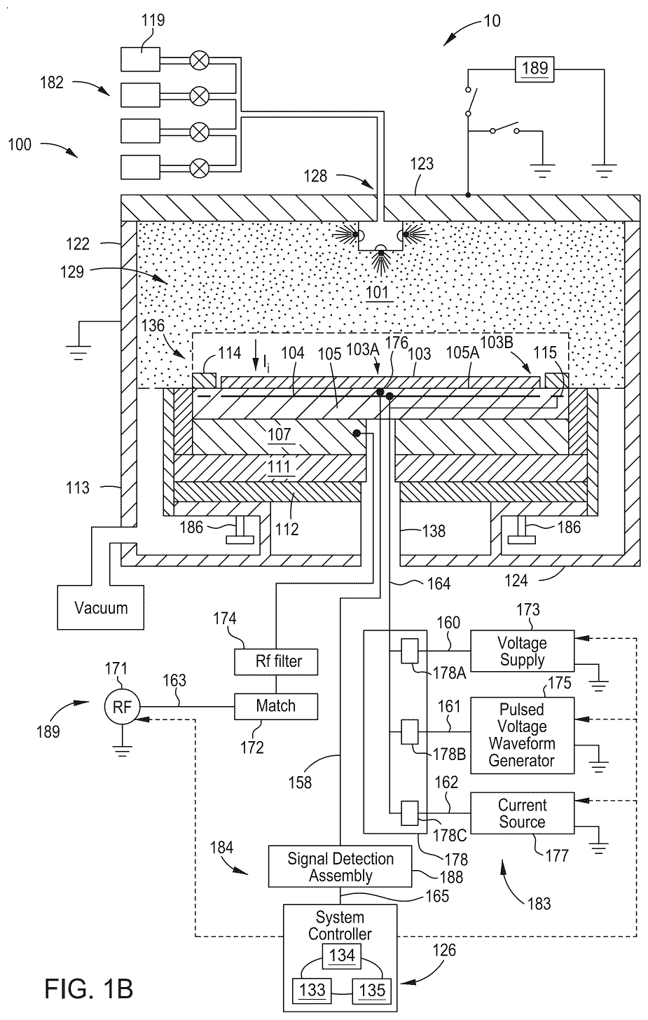

FIG. 1A is a schematic representation of a plasma processing system, in accordance with certain embodiments of the present disclosure.

FIG. 1B is a schematic detailed cross-sectional view of the plasma processing system, in accordance with certain embodiments of the present disclosure.

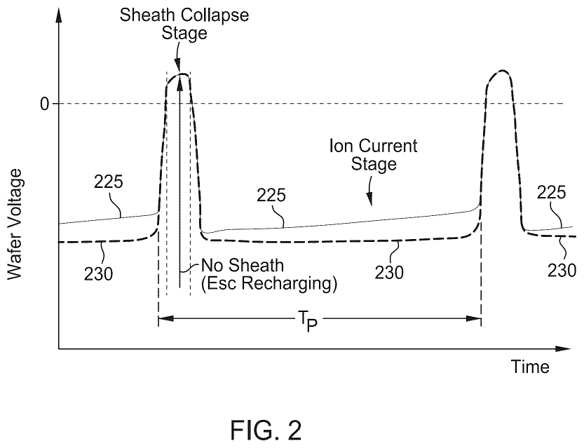

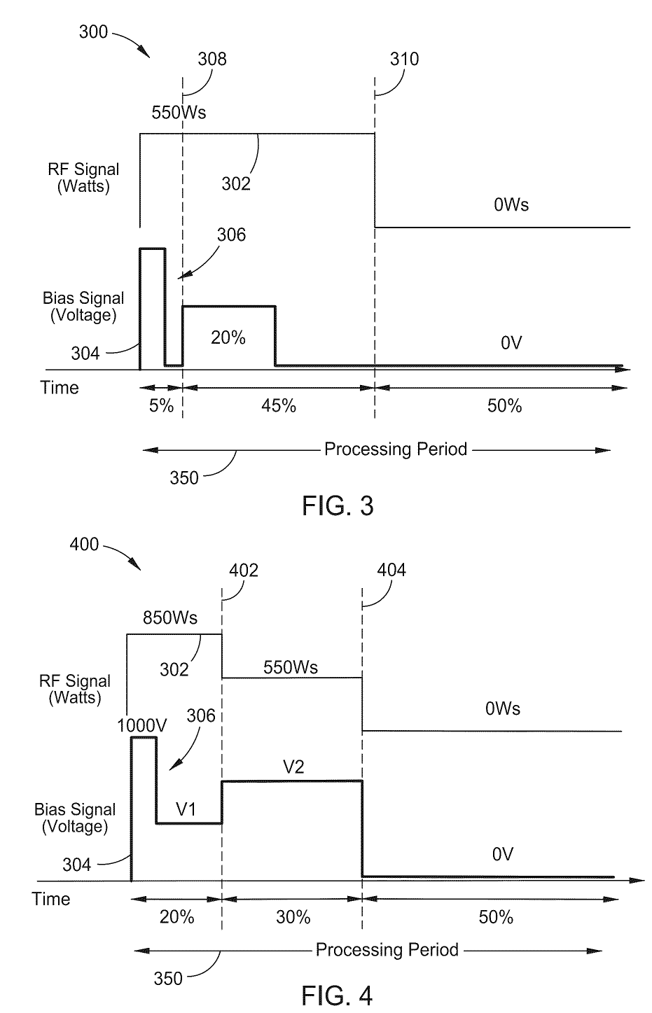

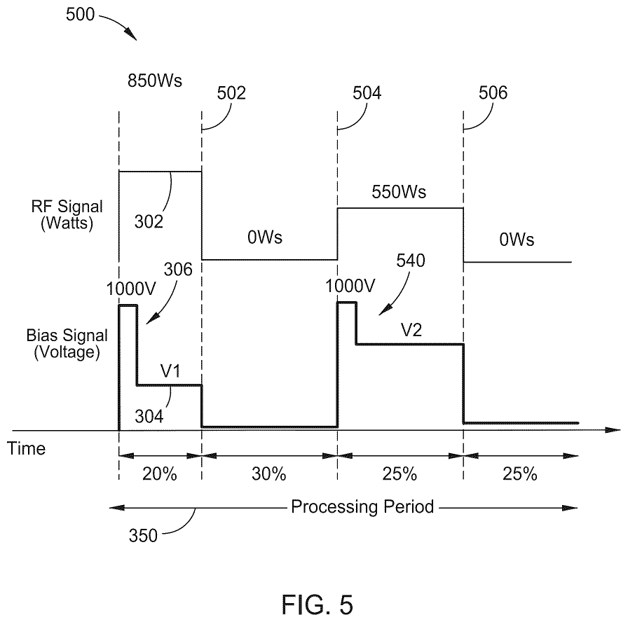

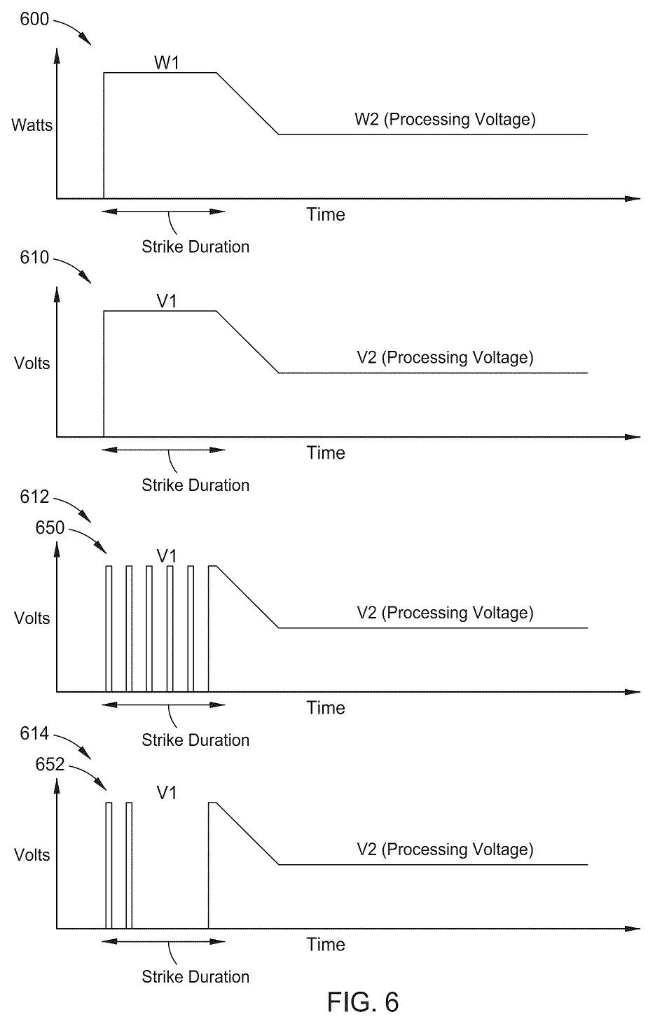

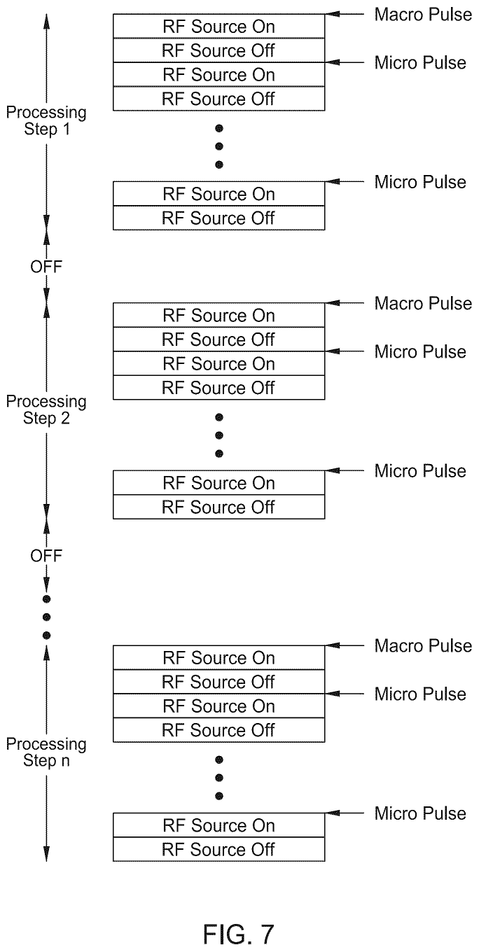

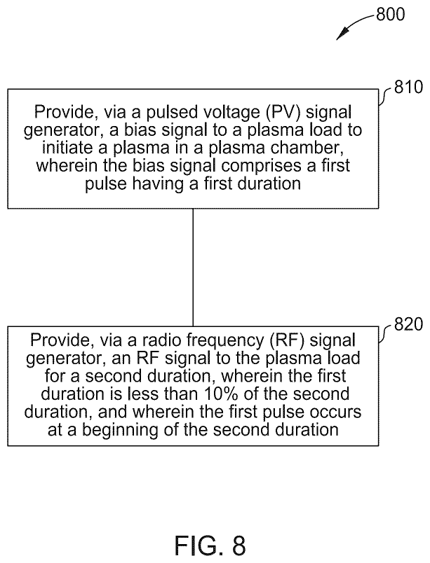

FIG. 2 shows a voltage waveform that is established on a substrate due to a voltage waveform applied to an electrode of a processing chamber, in accordance with certain embodiments of the present disclosure.

FIGS. 3-6 are graphs illustrating example pulsing schemes for semiconductor processing, in accordance with certain aspects of the present disclosure.

FIG. 7 illustrates a macro strike and micro bursts used to initiate and control plasma in a processing chamber, in accordance with certain aspects of the present disclosure.

FIG. 8 is a process flow diagram illustrating a method for processing a substrate in a plasma processing system, in accordance with certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a system used in a semiconductor device manufacturing process. More specifically, embodiments provided herein generally include apparatus and methods for plasma control in a processing chamber with increased reliability compared to conventional implementations. For example, one or more micro-bursts may be used to initiate and maintain a plasma during semiconductor processing. The one or more micro-bursts may be used to initiate plasma in the chamber after radio frequency (RF) power to the chamber has been turned off. The micro-burst allows the plasma to be initiated and maintained throughout a duration during which RF power is provided for semiconductor processing. Without the micro-burst, the plasma may be lost if the bias voltage level (and/or RF power level) used for semiconductor processing is too low, as described in more detail herein. Certain aspects of the present disclosure provide one or more advantages, such as the reliable control and maintenance of plasma in a processing chamber, providing more flexibility regarding the bias voltage level and/or RF power level used for semiconductor processing.

### Plasma Processing System Examples

FIG. 1A is a schematic representation of a plasma processing system. The plasma processing system 10 is configured for plasma-assisted etching processes, such as a reactive ion etch (RIE) plasma processing. The plasma processing system 10 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1A, the plasma processing system 10 is configured to form a capacitive coupled plasma (CPP). However, in some embodiments, a plasma may alternately be generated by an inductively coupled source disposed over a processing region of the plasma processing system 10.

The plasma processing system 10 includes a processing chamber 100, a substrate support assembly 136, a gas delivery system 182, a high DC voltage supply 173, a radio frequency (RF) generator 171, and an RF match 172 (e.g., RF impedance matching network). A chamber lid 123 includes one or more sidewalls and a chamber base that are configured to withstand the pressures and energy applied to them while a plasma 101 is generated within a vacuum environment maintained in a processing volume 129 of the processing chamber 100 during processing.

The gas delivery system 182, which is coupled to the processing volume 129 of the processing chamber 100 is configured to deliver at least one processing gas from at least one gas processing source 119 to the processing volume 129 of the processing chamber 100. The gas delivery system 182 includes the processing gas source 119 and one or more gas inlets 128 positioned through the chamber lid 123. The gas inlets 128 are configured to deliver one or more processing gasses to the processing volume 129 of the processing chamber 100.

The processing chamber 100 includes an upper electrode (e.g., the chamber lid 123) and a lower electrode (e.g., the substrate support assembly 136) positioned in the processing volume 129 of the processing chamber 100. The upper and lower electrodes face one another. In one embodiment, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode. For example, the RF generator 171 may deliver an RF source power to an RF baseplate within a cathode assembly (e.g., in the substrate support assembly 136) for plasma production, whereas the upper electrode is grounded. A center frequency of the RF source power can be from 13.56 MHz to very high frequency band such as 40 MHz, 60 MHz, 120 MHz or 162 MHz. In some examples, the RF source power can also be delivered through the upper electrode. The RF source power can be operated in a continuous mode or a pulsed mode. A pulsing frequency of the RF power can be from 100 to 10 kHz, and duty cycles are ranging from 5% to 95%. The RF generator 171 has a frequency tuning capability and can adjust its RF power frequency within e.g., ±5% or ±10%. In some embodiments, the RF generator 171 switches the RF power frequency at a predefined speed (e.g., two nanoseconds, fifty nanoseconds, etc.).

Referring to FIG. 1A and also FIG. 1B, which is a more detailed schematic cross-sectional view of the plasma processing system. The substrate support assembly 136 may be coupled to a high voltage DC supply 173 that supplies a chucking voltage thereto. The high voltage DC supply 173 may be coupled to a filter assembly 178 that is disposed between the high DC voltage supply 173 and the substrate support assembly 136.

The filter assembly 178 is configured to electronically isolate the high voltage DC supply 173 during plasma processing. In one configuration, a static DV voltage is between about −5000V and about 5000V, and is delivered using an electrical conductor (such as a coaxial power delivery line). The filter assembly 178 may include multiple filtering components or a single common filter.

The substrate support assembly 136 is coupled to a pulsed voltage (PV) waveform generator 175 configured to supply a PV to bias the substrate support assembly 136. The PV waveform generator 175 is coupled to the filter assembly 178. The filter assembly 178 is disposed between the PV waveform generator 175 and the substrate support assembly 136. The filter assembly 178 is configured to electronically isolate the PV waveform generator 175 during plasma processing.

The substrate support assembly 136 is coupled to the RF generator 171 configured to deliver an RF signal to the processing volume 129 of the processing chamber 100. The RF generator 171 is electronically coupled to the RF match 172 disposed between the RF generator 171 and the processing volume 129 of the processing chamber 100. For example, the RF match 172 is an electrical circuit used between the RF generator 171 and a plasma reactor (e.g., the processing volume 129 of the processing chamber 100) to optimize power delivery efficiency. One or more RF filters (e.g., within the RF match 172) are designed to only allow RF powers in a selected frequency range to pass, and to isolate RF power supplies from each other. In some cases, a bandwidth of an RF filter has to be larger than a frequency tuning range of the RF generator 171.

During the plasma processing, the RF generator 171 delivers an RF signal to the substrate support assembly 136 via the RF match 172. For example, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, some implementations find a match impedance (e.g., a matching point) by adjusting one or more components of the RF match 172 as the source and load impedances change.

The RF match 172 is electrically coupled to the RF generator 171, the substrate support assembly 136, and the PV waveform generator 175. The RF match 172 is configured to receive a synchronization signal from either or both of the RF generator 171 and the PV waveform generator 175.

The RF generator 171 and the PV waveform generator 175 are each directly coupled to a system controller 126. The system controller 126 synchronizes the respective generated RF signal and PV waveform.

Voltage and current sensors can be placed at an input and/or output of the RF match 172 to measure impedance and other parameters. These sensors can be synchronized using an external transistor-transistor logic (TTL) synchronization signal from an advanced waveform generator and/or RF generators or using measured voltage and current data to determine timing internally. For example, an output sensor 117 is configured to measure the impedance of the plasma processing chamber 100, and other characteristics such as the voltage, current, harmonics, phase, and/or the like. An input sensor 116 is configured to measure the impedance of the RF generator 171 and other characteristics such as the voltage, current, harmonics, phase, and/or the like. Based on either of the synchronization signals or the characteristics of the plasma processing chamber 100, the RF match 172 is able to capture fast impedance changes and optimize impedance matching.

The PV waveform generator 175 is used to supply a PV waveform and/or a tailored voltage waveform, which is a sum of harmonic frequencies associated with the waveform. The PV waveform generator 175 may output a synchronization TTL signal to the RF match 172. The voltage waveform is coupled to a bias electrode (e.g., a bias electrode 104 shown in FIG. 1B) through the filter assembly 178. The high DC voltage supply 173 is applied to chuck a substrate during a process for thermal control of the substrate. In some cases, there can be a third electrode at an edge of the cathode assembly for edge uniformity control.

FIG. 1B is a schematic detailed cross-sectional view of the plasma processing system 10. As shown in FIG. 1B, the plasma processing system 10 is configured to form a capacitively coupled plasma (CCP). However, in some embodiments, the plasma 101 may alternately be generated by an inductively coupled source disposed over the processing region of the plasma processing system 10. In this configuration, a coil may be placed on top of a ceramic lid (e.g., vacuum boundary) of the plasma processing chamber 100.

The plasma processing system 10 includes the processing chamber 100, the substrate support assembly 136, the gas delivery system 182, a DC power system 183, an RF power system 189, and the system controller 126. The processing chamber 100 includes a chamber body 113 that includes the chamber lid 123, one or more sidewalls 122, and a chamber base 124. The chamber lid 123, the one or more sidewalls 122, and the chamber base 124 collectively define the processing volume 129 of the processing chamber 100. The one or more sidewalls 122 and the chamber base 124 include materials (such as aluminum, aluminum alloys, or stainless steel alloys) that are sized and shaped to form a structural support for elements of the processing chamber 100 and are configured to withstand the pressures and added energy applied to them while the plasma 101 is generated within a vacuum environment maintained in the processing volume 129 of the processing chamber 100 during processing. A substrate 103 is loaded into, and removed from, the processing volume 129 of the processing chamber 100 through an opening (not shown) in one of the sidewalls 122. The opening is sealed with a slit valve (not shown) during plasma processing of the substrate 103.

The gas delivery system 182, which is coupled to the processing volume 129 of the processing chamber 100, includes the processing gas source 119 and the gas inlet 128 disposed through the chamber lid 123. The gas inlet 128 is configured to deliver one or more processing gases to the processing volume 129 of the processing chamber 100 from the processing gas source 119.

As noted above, the processing chamber 100 includes the upper electrode (e.g., the chamber lid 123) and the lower electrode (e.g., the substrate support assembly 136) disposed in the processing volume 129 of the processing chamber 100. The upper electrode and lower electrode are positioned to face each other. As seen in FIG. 1B, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode.

The substrate support assembly 136 includes a substrate support 105, a substrate support base 107, an insulator plate 111, a ground plate 112, a plurality of lift pins 186, one or more substrate potential sensing assemblies 184 (e.g., including a signal detecting assembly 188), and a bias electrode 104. Each of the lift pins 186 are disposed through a through hole 185 formed in the substrate support assembly 136 and are used to facilitate the transfer of the substrate 103 to and from a substrate receiving surface 105A of the substrate support 105. The substrate support 105 is formed of a dielectric material. The dielectric material can include a bulk sintered ceramic material, a corrosion-resistant metal oxide (for example, aluminum oxide (Al₂O₃), titanium oxide (TiO), yttrium oxide (Y₂O₃), a metal nitride material (for example, aluminum nitride (AlN), titanium nitride (TiN)), mixtures thereof, or combinations thereof.

The substrate support base 107 is formed of a conductive material (for example aluminum, an aluminum alloy, or a stainless steel alloy). The substrate support base 107 is electrically isolated from the chamber base 124 by the insulator plate 111, and the ground plate 112 interposed between the insulator plate 111 and the chamber base 124. The substrate support base 107 is configured to regulate the temperature of both the substrate support 105, and the substrate 103 disposed on the substrate support 105 during substrate processing. The substrate support base 107 includes one or more cooling channels (not shown) disposed therein that are fluidly coupled to, and in fluid communication with, a coolant source (not shown), such as a refrigerant source or substrate source having a relatively high electrical resistance. The substrate support 105 includes a heater (not shown) to heat the substrate support 105 and the substrate 103 disposed on the substrate support 105.

The bias electrode 104 is embedded in a dielectric material of the substrate support 105. The bias electrode 104 is formed of one or more electrically conductive parts. The electrically conductive parts include meshes, foils, plates, or combinations thereof. The bias electrode 104 functions as a chucking pole (i.e., electrostatic chucking electrode) that is used to secure (e.g., electrostatically chuck) the substrate 103 to the substrate receiving surface 105A of the substrate support 105. A parallel plate like structure is formed by the bias electrode 104 and a layer of the dielectric material that is disposed between the bias electrode 104 and the substrate receiving surface 105A. The dielectric material can have an effective capacitance C_{E} of between about 5 nF and about 50 nF. A layer of the dielectric material (e.g., aluminum nitride (AlN), aluminum oxide (Al₂O₃), etc.) has a thickness between about 0.3 mm and about 5 mm, such as between about 0.1 mm and about 3 mm, such as between about 0.1 mm and about 1 mm, or even between about 0.1 mm and 0.5 mm. The bias electrode 104 is electrically coupled to a clamping network, which provides a chucking voltage thereto. The clamping network includes the DC voltage supply 173 (e.g., a high voltage DC supply) that is coupled to a filter 178A of the filter assembly 178 that is disposed between the DC voltage supply 173 and the bias electrode 104. The filter 178A is a low-pass filter that is configured to block RF frequency and PV waveform signals provided by other biasing components found within the processing chamber 100 from reaching the DC voltage supply 173 during the plasma processing. The static DV voltage is between about −5000V and about 5000V, and is delivered using an electrical conductor (such as a coaxial power delivery line 106). The bias electrode 104 may bias the substrate 103 with the respect to the plasma 101 using one or more of the PV biasing schemes.

The substrate support assembly 136 includes an edge control electrode 115. The edge control electrode 115 is formed of one or more electrically conductive parts. The electrically conductive parts include meshes, foils, plates, or combinations thereof. The edge control electrode 115 is positioned below an edge ring 114 and surrounds the bias electrode 104 and/or is disposed a distance from a center of the bias electrode 104. For the processing chamber 100 that is configured to process circular substrates, the edge control electrode 115 is annular in shape, is made from a conductive material, and is configured to surround at least a portion of the bias electrode 104. As seen in FIG. 1B, the edge control electrode 115 is positioned within a region of the substrate support 105, and is biased by use of the PV waveform generator 175. The edge control electrode 115 is biased by use of a PV waveform generator that is different from the PV waveform generator 175 used for the bias electrode 104. The edge control electrode 115 is biased by splitting part of a signal provided from the PV waveform generator 175 to the bias electrode 104.

The DC power system 183 includes the DC voltage supply 173, the PV waveform generator 175, and a current source 177. The RF power system 189 includes the RF waveform generator 171, the RF match 172, and an RF filter 174. As shown in FIG. 1B, a power delivery line 163 electrically connects an output of the RF generator 171 to the RF match 172, the RF filter 174 and the substrate support base 107. As noted above, during the plasma processing, the DC voltage supply 173 provides a constant chucking voltage, while the RF generator 171 delivers the RF signal to the processing region, and the PV waveform generator 175 establishes the PV waveform at the bias electrode 104. For example, a sufficient amount of the RF power is applied to an RF bias voltage signal (which is also referred to herein as the RF waveform), and the RF waveform is provided to an electrode (e.g., the substrate support base 107) to cause the plasma 101 to be formed in the processing volume 129 of the processing chamber 100. The RF waveform has a frequency range between about 1 MHz and about 200 MHz, such as between 2 MHz and 40 MHz.

The DC power system 183 includes the filter assembly 178 to electrically isolate one or more of the components contained within the DC power system 183. A power delivery line 160 electrically connects an output of the DC voltage supply 173 to the filter assembly 178. A power delivery line 161 electrically connects the output of the PV waveform generator 175 to the filter assembly 178. A power delivery line 162 connects the output of the current source 177 to the filter assembly 178.

The current source 177 is selectively coupled to the bias electrode 104 by use of a switch (not shown) disposed in the power delivery line 162, to allow the current source 177 to deliver a desired current to the bias electrode 104 during one or more stages (e.g., ion current stage) of the voltage waveform generated by the PV waveform generator 175.

The filter assembly 178 includes multiple separate filtering components (i.e., discrete filters 178A-178C) that are each electrically coupled to an output node via a power delivery line 164. The filter assembly 178 may include one common filter electrically coupled to the output node via the power delivery line 164. The power delivery lines 160-164 include electrical conductors that include a combination of coaxial cables, such as a flexible coaxial cable that is connected in series with a rigid coaxial cable, an insulated high-voltage corona-resistant hookup wire, a bare wire, a metal rod, an electrical connector, of any combination of the above.

The system controller 126, also referred to herein as a processing chamber controller, includes a central processing unit (CPU) 133, a memory 134, and support circuits 135. The system controller 126 is used to control a process sequence used to process the substrate 103. The CPU is a computer processor configured for use in an industrial setting for controlling the processing chamber and sub-processors related thereto. The memory 134 described herein, which is generally non-volatile memory, can include random access memory, read-inly memory, hard disk drive, or other suitable forms of digital storage, local or remote. The support circuits 135 are coupled to the CPU 133 and include cache, clock circuits, input/output subsystems, power supplied, and the like, and combinations thereof. Software instructions (program) and data can be coded and stored within the memory 134 for instructing a processor within the CPU 133. A software program (or computer instructions) readable by the CPU 133 in the system controller 126 determines which tasks are performable by the components in the plasma processing system 10.

The program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 10 to perform the various process tasks and various process sequences used to implement the methods described herein. The program includes instructions that are used to perform one or more of the operations described herein.

FIG. 2 illustrates two separate voltage waveforms established at the substrate 103 disposed on the substrate receiving surface 105A of the substrate support assembly 136 of the processing chamber 100 due to the delivery of PV waveforms to the bias electrode 104 of the processing chamber 100 by use of the PV waveform generator 175. A first waveform (e.g., a waveform 225) is an example of a non-compensated PV waveform established at the substrate 103 during the plasma processing. A second waveform (e.g., a waveform 230) is an example of a compensated PV waveform established at the substrate 103 by applying a negative slope waveform to the bias electrode 104 of the processing chamber 100 during an “ion current stage” portion of the PV waveform cycle by use of the current source 177. The compensated PV waveform can alternatively be established by applying a negative voltage ramp during the ion current stage of the PV waveform generated by the PV waveform generator 175. The PV waveform cycle of the waveforms 225, 230 each have a period Tₚ, which is, for example, typically between 2 microsecond (μs) and 10 μs, such as 2.5 μs. The ion current stage of the PV waveform cycle will typically take up between about 50% and about 95% of the period Tₚ, such as from about 80% to about 90% of the period Tₚ.

The waveforms 225 and 230 include two main stages: an ion current stage and a sheath collapse stage. Both portions (e.g., the ion current stage and the sheath collapse stage) of the waveforms 225 and 230, can be alternately and/or separately established at the substrate 103 during the plasma processing. At a beginning of the ion current stage, a drop in the voltage at the substrate 103 is created, due to the delivery of a negative portion of the PV waveform (e.g., the ion current portion) provided to the bias electrode 104 by the PV waveform generator 175, which creates a high voltage sheath above the substrate 103. The high voltage sheath allows the plasma generated positive ions to be accelerated towards the biased substrate 103 during the ion current stage, and thus, for RIE processes, controls the amount and characteristics of the etching process that occurs on the surface of the substrate 103 during the plasma processing. In some embodiments, it is desirable for the ion current stage to include a region of the PV waveform that achieves the voltage at the substrate 103 that is stable or minimally varying throughout the stage, as illustrated in FIG. 2 by the waveform 230. One will note that significant variations in the voltage established at the substrate 103 during the ion current stage, such as shown by the positive slope in the waveform 225, will undesirably cause a variation in the ion energy distribution (IED) and thus cause undesirable characteristics of the etched features to be formed in the substrate 103 during the RIE process.

Plasma sheath impedance varies with supplied PV waveform voltages. The RF match 172 can use either or both of the synchronization signals and/or use its internal sensors to sample impedances in different processing phases. In one example, a synchronization signal or characteristics determined by the input sensor 116 or the output sensor 117 are used to trigger the RF match 172 to determine at least two different impendences at different processing stages. Then, the RF match 172 updates its matching point based on the at least two different impedances.

Silicon Carbide (SiC)-based Schottky diodes exhibit low junction capacitance (e.g., in the order of tens of picofarads) when reverse-biased to a certain extent. If such a reverse-biased Schottky diode stack with low junction capacitance is placed in the path of an RF signal (e.g., having a frequency of 13.56 MHz), the diode provides high impedance for the RF signal, thereby blocking the RF signal. On the flip side, when forward-biased, the same Schottky diode stack allows the RF signal to pass through as the diode acts as a shorted path under the influence of forward bias. Therefore, the Schottky diode can act as an RF switch (RFS) by virtue of a circuit that can switch between the forward bias and the reverse bias states at the PV waveform frequency. This scheme allows a user to change the overall impedance of a matching network at a higher frequency than conventional implementations by turning on and off the RF switch using a reverse and forward bias. Traditional matching networks may be unable to tune at such high frequencies.

### Pulsed Voltage-Assisted Plasma Strike

Some implementations use bias power in combination with a source provided power to enhance plasma ignition. In some aspects, a pulsed voltage (PV) may be used to enhance plasma ignition with PV waveform parameters set to improve voltage delivery. Using a PV waveform, multi-level pulsing capabilities may enhance plasma ignition on macro-scale and micro-scale timescales.

Certain aspects implement a PV blended strike capability by providing a pulsed voltage burst before or at the beginning of a RF source sequence. Ignition parameters may be tuned based on experiments to characterize strike performance, providing repeatability of ignition and reducing reflected power. Certain aspects implement a strike via a recipe setting. More complex ignition sequences, such as bias signal slope tuning, may be implemented to improve ignition. In some cases, multiple bursts may be used to reduce the impact on semiconductor processing, as described in more detail herein.

FIGS. 3-5 are graphs 300, 400, 500 illustrating example pulsing schemes for semiconductor processing, in accordance with certain aspects of the present disclosure. Pulsing schemes that include a source off state (e.g., a state where the RF source from generator 171 is off) may result in plasma stability issues. Certain aspects of the present disclosure are directed to providing a series of pulsed voltages (e.g., a micro-burst) at a high voltage (e.g., equal to or greater than 1000V) as a bias for semiconductor processing. Using a high-voltage burst may put restrictions on the process space, especially with regard to logic recipes that have lower voltage specifications or requirements. Some aspects are directed to using at least one micro-burst (e.g., including less than fifteen low-time duration pulses) with each RF power burst for source recoupling. The delivery of the micro-burst helps to initiate and maintain the plasma. After the micro-burst, the bias voltage may be reduced below high voltage (e.g., 1000V) to facilitate a semiconductor processing recipe. A micro-burst refers to a series of pulses at a specific frequency, such as 400 KHz as described with respect to FIG. 2.

While, for simplicity of illustration purposes, the bias signals illustrated in the figures provided herein are represented as increasing in magnitude from a zero reference the actual bias signal applied in any of the embodiments disclosed herein can have either a positive or negative polarity. In one or more embodiments, an applied bias signal applied to an electrode within the plasma processing chamber substantially has a negative polarity relative to a ground reference.

As shown in FIG. 3, graph 300 illustrates a voltage of a bias signal 304 (e.g., PV signal from PV waveform generator 175) and an RF power pulse 302 (in Watts (Ws)) of an RF signal (e.g., sinusoidal signal) from an RF source (e.g., RF generator 171). The bias signal 304 may be applied to any electrode that is capacitively coupled to the chamber. For example, the bias signal 304 may be applied to the bias electrode 104 described with respect to FIG. 1B or an edge electrode (e.g., edge ring) of the chamber.

A micro-burst 306 (e.g., a series of pulses having a 1000V peak) may be applied via the PV waveform generator 175. The burst may begin along with the RF power pulse 302 increasing in accordance with a certain processing recipe. For example, the burst 306 may be applied along with the RF power increasing to 550 watts, as shown. After the micro-burst 306, the voltage of the bias signal 304 may be set based on the needs of the plasma processing recipe. For example, as shown in graph 300, the voltage of the bias signal 304 may be reduced to 0 volts until time 308. Then, the voltage of the bias signal 304 may increase (e.g., to 500 volts) and decrease back to 0 volts after some time has elapsed, as shown. In this case, the power pulse 302 of the RF signal may reduce to 0 watts at time 310, as shown. The micro-burst 306 allows the plasma to be initiated and maintained while the RF power is being provided during a portion of a processing period 350 (e.g., anywhere between 100 microseconds (μs) to 100 milliseconds (ms). While portions of the bias signal 304 are shown as a constant voltage (e.g., a constant voltage at a voltage V1), the bias signal 304 includes a series of pulses (e.g., at 400 KHz as shown in FIG. 2). The voltage of the bias signal shown represents the peak voltage of the pulses. For example, the burst 306 may include a series of pulses having a peak voltage of 1000 volts.

The bias voltage and RF power during the processing period may be in accordance with a processing recipe. For example, as shown, the duration between the beginning of the burst 306 and time 308 may be 5% of the total processing period 350. The duration during which the voltage of the bias signal is set to 300 volts may be 20% of the processing period 350. The duration between time 308 and time 310 may be 45% of the processing period 350 and the duration from time 310 until the end of the processing period 350 may be 50% of the processing period 350. The pulsing sequence performed by the bias signal 304 and the RF power pulse 302 during the processing period 350 may be repeated one or more times as desired.

The micro-burst 306 may be used to facilitate the initiation and maintenance of plasma for any processing recipe, such as the processing recipes described with respect to FIGS. 3-5. For instance, as shown in FIG. 4, after the burst 306, the voltage of the bias signal may decrease to a voltage V1 (e.g., 300 volts) until time 402. Then, the voltage of the bias signal may increase to a voltage V2 (e.g., 500 volts) until time 404, after which the voltage of the bias signal may decrease to 0 volts. The RF signal power pulse 302 may be 850 watts until time 402, then reduced to 550 watts until time 404, then reduced to 0 Watts, as shown.

The duration of micro-burst 306 may be relatively short in order to avoid any adverse impact (e.g., unwanted etching or mask damage) on the semiconductor being processed. Thus, the voltage and duration of the burst 306 may be selected to initiate and properly maintain the plasma in the chamber but not adversely impact the semiconductor processing. In some cases, the duration (e.g., 10 microseconds to 200 microseconds) of the burst 306 may be, for example, 2% or less of the processing period 350 or 5% or less than a duration during which RF power is provided to the chamber. The micro-burst may be used to initiate and maintain the plasma whenever the RF source power has been 0 Watts for longer than a certain duration.

As another example shown in FIG. 5, after burst 306, the voltage of the bias signal 304 may be reduced to V1 (e.g., the peak voltage of pulses forming the bias signal 304 may be 300 volts) until time 502 after which the voltage of the bias signal 304 may be reduced to 0 volts. As shown, the RF signal power pulse 302 may be set to a first power (e.g., 850 Watts) from the beginning of the processing period until time 502, then reduced to 0 Watts as shown. The example pulsing scheme shown in FIG. 5 may include two RF power bursts, each beginning with a micro-burst. For example, at time 504, another burst 540 may be provided, after which the voltage of the bias signal 304 may be reduced to a voltage V2 (e.g., where V2 is greater than V1) until time 506 after which the voltage of the bias signal 304 is reduced 0 volts. The RF signal power may be set to a second power (e.g., 550 Watts) less than the first power between times 504, 506, and then reduced 0 Watts, as shown. The duration from the beginning of the processing period 350 until time 502 may be 20% of the processing period 350. The duration between times 502, 504 may be 30% of the processing period 350. The duration between times 504, 506 may be 25% of the processing period 350, and the duration from time 506 until the end of the processing period 350 may be 25% of the processing period 350.

While some examples described herein use a single burst to initiate and maintain the plasma in the chamber, any suitable number of bursts may be used. For example, five bursts may be used to initiate and maintain the plasma in the chamber. In some cases, more bursts may be used if the plasma in the chamber has been off for an extended period of time.

In some cases, a macro-strike scheme may be used to initiate the plasma in the chamber, as described in more detail with respect to FIG. 6. For example, the macro-strike scheme may be used when the RF source has been off for an extended period of time such as during a period between processing steps.

FIG. 6 illustrates a macro-strike scheme, in accordance with certain aspects of the present disclosure. As shown in graph 600, the RF source power may be increased to W1 at the beginning of the processing period. As shown in graph 610, the voltage of the bias signal may be increased to V1, providing a macro-strike to initiate the plasma. The RF signal power and the voltage of the bias signal may be set to W1 and V1, respectively, for a macro-strike duration to initiate the plasma in the chamber. After the macro-strike duration, the RF signal power may be adjusted to W2 and the voltage of the bias signal may be adjusted to V2 for semiconductor processing. While in graphs 600, 610 the power W2 for semiconductor processing is less than W1 and the bias signal voltage V2 is less than V1, in some cases, W2 may be more than W1 and V2 may be more than V1. The macro-strike duration may be long (e.g., one second) when the plasma has been off for an extended period of time, such as for a cold start of the chamber.

FIG. 7 illustrates a macro strike and a series of micro bursts used to initiate and control plasma in a processing chamber, in accordance with certain aspects of the present disclosure. As shown, semiconductor processing may involve multiple processing steps 1-n, n being a positive integer. Each of the processing steps may be associated with a certain processing recipe (e.g., set pressure, RF power, bias voltage, and/or temperatures). Between the processing steps, the RF power may be turned off (e.g., may be zero) during which chamber conditions are stabilized, as shown. At the beginning of each processing step (e.g., where RF power has been off for an extended period of time), a macro-strike as described with respect to graph 610 of FIG. 6 may be used to initiate the plasma in the chamber. Within each processing step, a pulsing scheme (e.g., 100 KHz pulsing) may be used where the RF source may be turned on and off, providing multiple RF power phases. Each time the RF source is turned on (e.g., at the beginning of each of the RF power phases other than an initial RF power phase of the step), a micro-burst (e.g., a single burst) may be used to initiate and maintain the plasma.

If the macro-strike duration is too long relative to the processing period, the macro-strike period may adversely impact the processing of the semiconductor. In other words, a long macro-strike duration may place stress on the semiconductor. In some aspects of the present disclosure, the macro-strike duration may be implemented with (e.g., replaced with) multiple micro-bursts 650, as shown in graph 612 in FIG. 6. The micro-bursts may be implemented as a series of bursts with a 1-10% duty cycle and a certain frequency. That is, the duration of each burst may be 1-10% of the total duration from a beginning of one burst to a following burst. The strike duration including the bursts 650 may be, for example, one second or less. In any of the various bursts disclosed herein, the duty cycle of the pulses (e.g., ratio of voltage “on time” (e.g., “ion current stage”) to the period (Tp) of the pulse (FIG. 2)) provided within a burst can be, for example, between about 50% and about 95%.

While five bursts are shown in graph 612 to facilitate understanding, any suitable number of bursts may be used. For example, as shown in graph 614, two micro-bursts 652 may be used. The strike-duration may be implemented with bursts that have a 1-10% duty cycle for one second, where each bursts includes a series of pulses that may be have a frequency of 400 KHz.

Certain aspects of the present disclosure are directed towards controlling the slope of pulses (e.g., pulses as shown in FIG. 2) to initiate and maintain the plasma in the chamber more efficiently. The slope of a PV signal pulse (e.g., controlling the rise and fall times of the PV for the sheath collapse stage as described with respect to FIG. 2) may be controlled to provide a pulse shape to improve processing performance. Although the slope control improves processing performance, the slope control may negatively impact striking (e.g., plasma initiation). For plasma initiation, providing faster rise and fall times of the PV signal allows for a more efficient plasma strike. With faster rise and fall times, the voltage of the micro-burst for plasma initiation may be reduced, reducing the risk of damage to the semiconductor or chamber when striking the plasma in the chamber. In other words, assuming a typical rise and fall time for the PV signal is 300 us for semiconductor processing, the rise and fall times may be reduced to be as low as 20-30 us for plasma initiation.

FIG. 8 is a process flow diagram illustrating a method 800 for processing a substrate in a plasma processing system, in accordance with certain embodiments of the present disclosure. The method 800 can be performed by a plasma processing system.

At operation 810, the plasma processing system provides, via a PV signal generator, a bias signal to a plasma load to initiate a plasma in a plasma chamber. The bias signal may include a first burst (e.g., a micro-burst, such as the burst 306 of FIG. 3) having a first duration.

At operation 820, the plasma processing system provides, via an RF signal generator, an RF signal to the plasma load for a second duration. The first duration may be less than 10% of the second duration. The first burst may occur at a beginning of the second duration. The RF signal may have different power levels during the second duration.

The bias signal may include at least one second burst (e.g., burst 540) each having a third duration. The third duration may be less than 10% of the second duration. The third duration may be equal to the first duration.

The first burst may have a first voltage. The bias signal may have a second voltage after the first duration that is less than the first voltage. The second voltage may be in accordance with a semiconductor processing recipe.

In some aspects, the plasma processing system generates, via the PV signal generator, multiple bursts including the first burst to initiate the plasma in the plasma chamber at a beginning of an initial RF power phase in each of multiple semiconductor processing steps (e.g., processing steps 1-n shown in FIG. 7). Each of the multiple semiconductor processing steps may include multiple RF power phases. The plasma processing system may generate, via the PV signal generator, a single burst to initiate the plasma in the plasma chamber at a beginning of each of the multiple RF power phases after the initial RF power phase. The RF signal generator may transition from providing zero power to providing power greater than zero at the beginning of each of the multiple RF power phases.

In some aspects, the plasma processing system may generate at least one second burst for semiconductor processing. Rise and fall times of one or more pulses of the first burst may be less than rise and fall time of one or more pulses of the at least one second pulse.

While the foregoing is directed to embodiments of the present disclosure, other and further embodiments of the disclosure may be devised without departing from the basic scope thereof, and the scope thereof is determined by the claims that follow.

What is claimed is:

1. An apparatus for processing a substrate in a plasma processing system, comprising:
a pulsed voltage (PV) signal generator configured to provide a bias signal to a plasma load to initiate a plasma in a plasma chamber, wherein the bias signal comprises a first burst having a first duration, the first burst including a series of pulses; and
a radio frequency (RF) signal generator configured to provide an RF signal to the plasma load for a second duration, wherein the first duration is less than 10% of the second duration, and wherein the first burst occurs at a beginning of the second duration.

2. The apparatus of claim 1, wherein the RF signal has different power levels during the second duration.

3. The apparatus of claim 1, wherein the bias signal comprises at least one second burst each having a third duration, wherein the third duration is less than 10% of the second duration.

4. The apparatus of claim 3, wherein the third duration is equal to the first duration.

5. The apparatus of claim 1, wherein the first burst has a first voltage, and wherein the bias signal has a second voltage after the first duration that is less than the first voltage.

6. The apparatus of claim 5, wherein the second voltage is in accordance with a semiconductor processing recipe.

7. The apparatus of claim 1, wherein the PV signal generator is configured to:
generate a series of bursts including the first burst to initiate the plasma in the plasma chamber at a beginning of an initial RF power phase in each of multiple semiconductor processing steps, wherein each of the multiple semiconductor processing steps comprises multiple RF power phases; and
generate a single burst to initiate the plasma in the plasma chamber at a beginning of each of the multiple RF power phases after the initial RF power phase.

8. The apparatus of claim 7, wherein the RF signal generator is configured to transition from providing zero power to providing power greater than zero at the beginning of each of the multiple RF power phases.

9. The apparatus of claim 1, wherein the PV signal generator is configured to generate at least one second burst for semiconductor processing, and wherein rise and fall times of one or more pulses of the first burst are less than rise and fall time of one or more pulses of the at least one second burst.

10. A method for processing a substrate in a plasma processing system, comprising:
providing, via a pulsed voltage (PV) signal generator, a bias signal to a plasma load to initiate a plasma in a plasma chamber, wherein the bias signal comprises a first burst having a first duration, the first burst including a series of pulses; and
providing, via a radio frequency (RF) signal generator, an RF signal to the plasma load for a second duration, wherein the first duration is less than 10% of the second duration, and wherein the first burst occurs at a beginning of the second duration.

11. The method of claim 10, wherein the RF signal has different power levels during the second duration.

12. The method of claim 10, wherein the bias signal comprises at least one second burst each having a third duration, wherein the third duration is less than 10% of the second duration.

13. The method of claim 12, wherein the third duration is equal to the first duration.

14. The method of claim 10, wherein the first burst has a first voltage, and wherein the bias signal has a second voltage after the first duration that is less than the first voltage.

15. The method of claim 14, wherein the second voltage is in accordance with a semiconductor processing recipe.

16. The method of claim 10, further comprising:
generating, via the PV signal generator, a series of bursts including the first burst to initiate the plasma in the plasma chamber at a beginning of an initial RF power phase in each of multiple semiconductor processing steps, wherein each of the multiple semiconductor processing steps comprises multiple RF power phases; and
generating, via the PV signal generator, a single burst to initiate the plasma in the plasma chamber at a beginning of each of the multiple RF power phases after the initial RF power phase.

17. The method of claim 16, further comprising transitioning from providing zero power to providing power greater than zero at the beginning of each of the multiple RF power phases.

18. The method of claim 10, further comprising generating at least one second burst for semiconductor processing, and wherein rise and fall times of one or more pulses of the first burst are less than rise and fall time of one or more pulses of the at least one second burst.

19. A plasma processing system, comprising:
a plasma chamber;
a pulsed voltage (PV) signal generator coupled to the plasma chamber and configured to provide a bias signal to a plasma load to initiate a plasma in the plasma chamber, wherein the bias signal comprises a first burst having a first duration, the first burst including a series of pulses; and
a radio frequency (RF) signal generator coupled to the plasma chamber and configured to provide an RF signal to the plasma load for a second duration, wherein the first duration is less than 10% of the second duration, and wherein the first burst occurs at a beginning of the second duration.

20. The plasma processing system of claim 1, wherein the bias signal comprises at least one second burst each having a third duration, wherein the third duration is less than 10% of the second duration.
